(19) United States
(12) Patent Application Publication
(10) Pub. No.: US 2026/0245631 A1
(43) Pub. Date: Aug. 20, 2026

(54) SEMICONDUCTOR MEMORY DEVICE

(71) Applicant: SK hynix Inc., Icheon-si (KR)

(72) Inventors: Jong Il LEE, Icheon-si (KR); Myoung Kun SONG, Icheon-si (KR); Seung Wan CHAE, Icheon-si (KR)

(21) Appl. No.: 19/540,676

(22) Filed: Feb. 14, 2026

(30) Foreign Application Priority Data
Feb. 14, 2025 (KR) 10-2025-0019078

(51) Int. Cl. G11C 16/26; G11C 5/06; G11C 16/04; G11C 16/08; G11C 16/30; G11C 16/32

(52) U.S. Cl. CPC G11C 16/26; G11C 5/063; G11C 16/0483; G11C 16/08; G11C 16/30; G11C 16/32

(57) ABSTRACT

A semiconductor memory device includes: a memory block including a plurality of memory cells; a first wordline connected to a selected memory cell among the plurality of memory cells; a second wordline disposed adjacent to the first wordline; and a row decoder configured to transmit a first pass voltage to the second wordline in a first read section and to transmit a second pass voltage lower than the first pass voltage to the second wordline in a second read section.

### CROSS-REFERENCE TO RELATED APPLICATION

This patent document claims priority under 35 U.S.C. §119(a) and the benefits of Korean patent application No. 10-2025-0019078, filed in the Korean Intellectual Property Office on February 14, 2025, the disclosure of which is incorporated herein by reference in its entirety as part of the disclosure of this patent document.

### TECHNICAL FIELD

The technology and implementations disclosed in this patent document generally relate to a semiconductor memory device for storing data therein.

### BACKGROUND

A semiconductor memory device may include a plurality of memory cells for storing data therein. In addition, the semiconductor memory device may be classified as a nonvolatile memory device that can maintain stored data even when power supply is interrupted, or as a volatile memory device that does not preserve data when power supply is interrupted.

Examples of a nonvolatile memory device may include a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), or a ferroelectric RAM (FRAM), and the like.

### SUMMARY

Various embodiments of the present disclosure relate to a semiconductor memory device having an improved operating speed.

In accordance with an embodiment of the present disclosure, a semiconductor memory device may include: a memory block including a plurality of memory cells; a first wordline connected to a selected memory cell from among the plurality of memory cells; a second wordline disposed adjacent to the first wordline; and a row decoder configured to transmit a first pass voltage to the second wordline in a first read time period and to transmit a second pass voltage lower than the first pass voltage to the second wordline in a second read time period.

In accordance with another embodiment of the present disclosure, a method for operating a semiconductor memory device may include: increasing voltages of a first wordline connected to a selected memory cell from among multiple memory cells, and a second wordline disposed adjacent to the first wordline to a first pass voltage; applying the first pass voltage to the second wordline in a first read section; and applying a second pass voltage lower than the first pass voltage to the second wordline in a second read section.

In accordance with another embodiment of the present disclosure, a semiconductor memory device may include: a memory block including a plurality of memory cells; a selected wordline connected to a selected memory cell from among the plurality of memory cells; and an unselected wordline disposed adjacent to the selected wordline and configured to sequentially receive a first pass voltage and a second pass voltage lower than the first pass voltage in an operation for reading one or more bits stored in the selected memory cell.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an example of a memory system according to an embodiment of the present disclosure.

FIG. 2 is a block diagram illustrating an example of a memory device shown in FIG. 1 according to an embodiment of the present disclosure.

FIG. 3 is a diagram illustrating an example of a memory block shown in FIG. 2 according to an embodiment of the present disclosure.

FIG. 4A is a diagram illustrating a threshold voltage distribution of memory cells included in a memory block shown in FIG. 3 according to an embodiment of the present disclosure.

FIG. 4B is a table illustrating an order of using read voltages in a read operation with respect to a threshold voltage distribution of memory cells shown in FIG. 4A according to an embodiment of the present disclosure.

FIG. 5 is a graph illustrating an example of voltages applied to a selected wordline and an unselected wordline during a read operation according to an embodiment of the present disclosure.

FIG. 6 is a graph illustrating example actions of wordlines in response to voltages changing as shown in FIG. 5 according to an embodiment of the present disclosure.

### DETAILED DESCRIPTION

This patent document provides implementations and examples of a semiconductor memory device for storing data therein that may be used in configurations to substantially address one or more technical or engineering issues and to mitigate limitations or disadvantages encountered in other semiconductor memory devices. Some implementations of the present disclosure relate to a semiconductor memory device having an improved operating speed. In recognition of the issues above, the semiconductor memory devices according to the embodiments of the present disclosure may reduce the amount of time required for setting voltages for a selected wordline and an unselected wordline, thereby improving the speed of a read operation.

Reference will now be made in detail to the embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

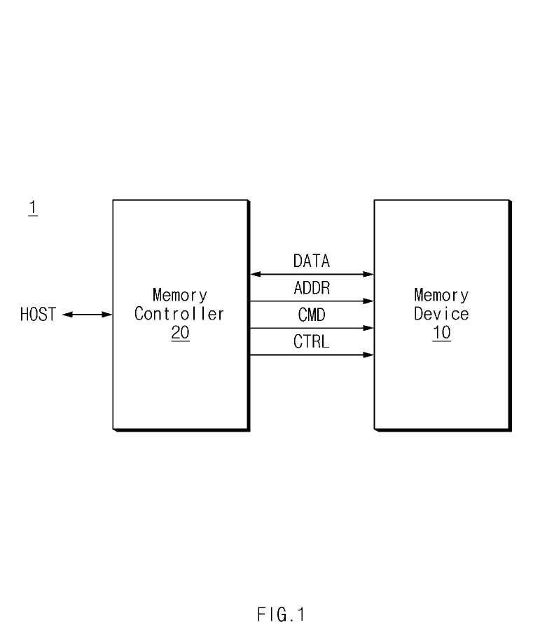

FIG. 1 is a block diagram illustrating an example of a memory system according to an embodiment of the present disclosure.

Referring to FIG. 1, a memory system 1 may include a memory device 10 and a memory controller 20.

The memory system 1 may be implemented as an internal memory embedded in an electronic system (e.g., a smartphone, a tablet, a computer, a TV, etc.). For example, the memory system 1 may be an embedded universal flash storage (UFS), an embedded multimedia card (eMMC), or a solid state drive (SSD). According to one embodiment, the memory system 1 may be implemented as an external memory detachably coupled to an electronic device, and may be, for example, a UFS memory card, a compact flash (CF) card, a secure digital (SD) card, a micro-Secure Digital (micro-SD) card, a mini-Secure Digital (mini-SD) card, an eXtreme Digital (xD) card, or a memory stick.

The memory system 1 may store data, received from a host, in the memory device 10 based on an access request from the host, or may read data requested by the host from the memory device 10 and transmit the read data to the host.

The memory device 10 may include a plurality of memory cells, each of which stores data. According to an embodiment, each of the plurality of memory cells may be a nonvolatile memory cell that maintains stored data even when power supply is interrupted. For example, when the memory cell is a nonvolatile memory cell, the memory device 10 may be implemented as an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like. Hereinafter, embodiments of the present disclosure will be described as examples in which the plurality of memory cells is NAND flash memory cells, but the technical idea of the present disclosure is not limited thereto. The memory device 10 may perform program, read, and/or erase operations under control of the memory controller 20.

The memory controller 20 may provide a control signal (CTRL), a command (CMD), and an address (ADDR) to the memory device 10. The control signal (CTRL) may include information necessary for the memory device 10 to perform an operation corresponding to the command (CMD) received from the memory controller 20. For example, the control signal (CTRL) may include information about the sensing parameters necessary for the memory device 10 to read data from memory cells. The command (CMD) may indicate an operation to be performed by the memory device 10 during the program, read, or erase operations. The address (ADDR) may indicate a position at which the memory controller 20 desires to access data in the memory device 10. Data (DATA) may be transmitted and/or received between the memory controller 20 and the memory device 10 based on the command (CMD) and the address (ADDR).

The memory controller 20 may control various operations of the memory device 10 in response to an access request from the host, such as for example, a program operation for programming data (DATA) in the memory device 10, a read operation for reading data (DATA) from the memory device 10, and/or an erase operation for erasing data (DATA) of the memory device 10. For example, the memory controller 20 may transmit data (DATA) received from the host to the memory device 10 by executing a write command, or may transmit data (DATA) read from the memory device 10 to the host by executing a read command. In addition, the memory controller 20 may provide a clock signal, a chip selection signal, etc. to the memory device 10.

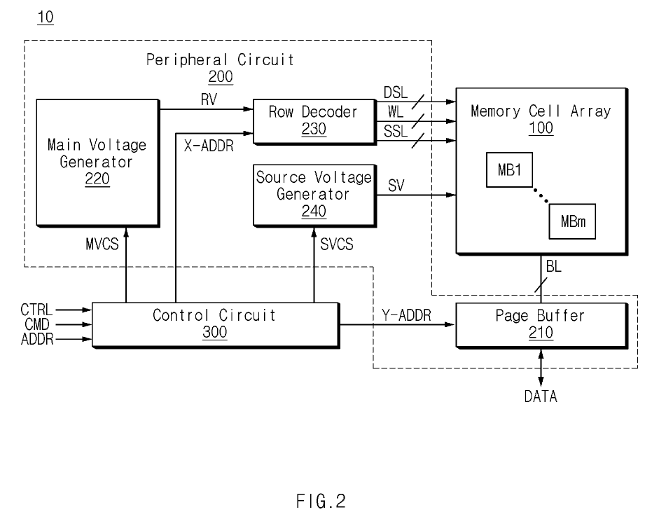

FIG. 2 is a block diagram illustrating an example of a memory device shown in FIG. 1 according to an embodiment of the present disclosure.

Referring to FIG. 2, a memory device 10 may include a memory cell array 100, a peripheral circuit 200, and a control circuit 300. According to an embodiment, although not shown in FIG. 2, the memory device 10 may further include a data input/output (I/O) circuit for communication with an external device including a memory controller 20, or an input/output (I/O) interface for communication with a different external device.

The memory cell array 100 may include a plurality of memory cells. The memory cell array 100 may be connected to drain selection lines (DSLs), wordlines (WLs), source selection lines (SSLs), and bitlines (BLs). The memory cell array 100 may be connected to a row decoder 230 through the drain selection lines (DSLs), the wordlines (WLs), and the source selection lines (SSLs), and may be connected to a page buffer circuit 210 through the bitlines (BLs).

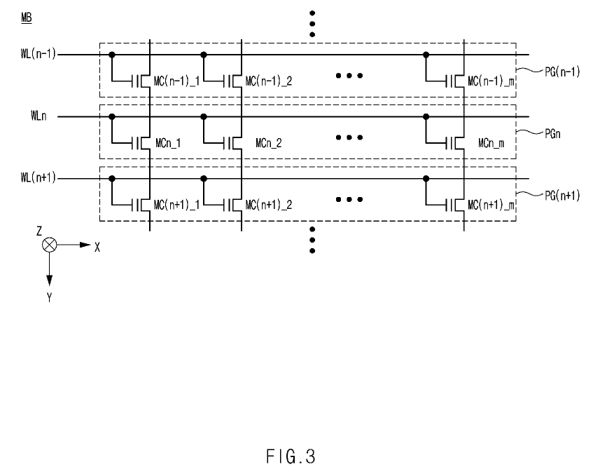

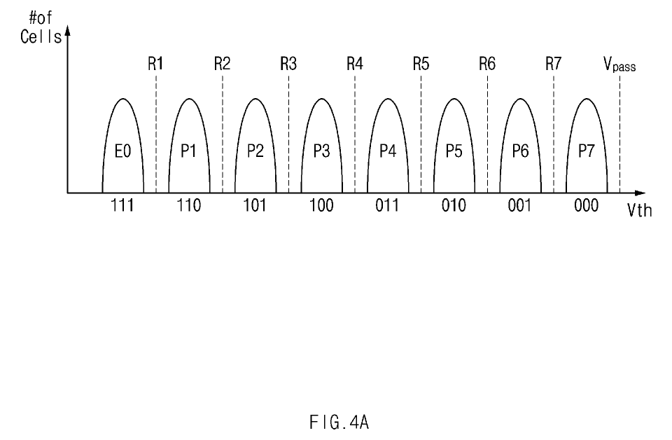

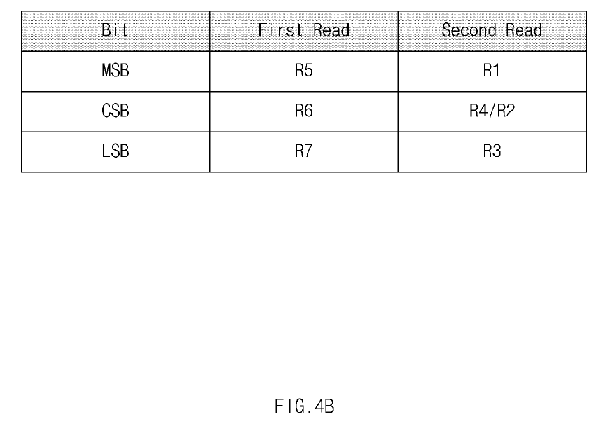

The memory cell array 100 may include a plurality of memory blocks (MB1–MBm), where ‘m’ is an integer of 2 or greater. Each memory block may include a plurality of memory cells arranged in a two-dimensional (2D) structure or a three-dimensional (3D) structure. According to an embodiment, each memory block (MB1–MBm) may be or include at least one of a single-level cell (SLC) block including single-level cells (SLCs), a multi-level cell (MLC) block including multi-level cells (MLCs), a triple-level cell (TLC) block including triple-level cells (TLCs), or a quad-level cell (QLC) block including quad-level cells (QLCs). The structure of each memory block (MB1–MBm) will be described later with reference to FIGS. 3, 4A and 4B.

The peripheral circuit 200 may control the operation of the memory cell array 100 while under the control of the control circuit 300. The peripheral circuit 200 may include the page buffer circuit 210, a main voltage generator 220, the row decoder 230, and a source voltage generator 240.

The page buffer circuit 210 may operate in response to a control signal of the control circuit 300. The page buffer circuit 210 may select some bitlines among the bitlines (BLs) in response to a column address (Y-ADDR). For example, the page buffer circuit 210 may operate as a write driver or a sense-amplifier.

According to an embodiment, during the program operation, the page buffer circuit 210 may operate as a write driver to transmit a voltage according to data (DATA) to be stored in the memory cell array 100 to the bitlines (BLs). According to an embodiment, during the read operation, the page buffer circuit 210 may operate as a sense-amplifier to detect data (DATA) stored in the memory cell array 100 received through the bitlines (BLs). The page buffer circuit 210 may detect data (DATA) using a read judgment voltage (RJV) received from the control circuit 300. For example, the page buffer circuit 210 may determine data (DATA) by comparing a voltage level of a signal received through the bitline (BL) with the read judgment voltage (RJV).

The main voltage generator 220 may generate various types of reference voltages (RV) required to perform a program operation, a read operation, and an erase operation on the memory cell array 100 based on a main voltage control signal (MVCS). Specifically, the main voltage generator 220 may generate a wordline voltage (for example, a program voltage, a read voltage, a pass voltage, an erase voltage, a verification voltage, e.g., an erase verification voltage or a program verification voltage) to be applied to a wordline (WL), and may further generate a drain selection line voltage to be applied to a drain selection line (DSL) and a source selection line voltage to be applied to a source selection line (SSL). That is, the reference voltages (RVs) may include a wordline voltage, a drain selection line voltage, and a source selection line voltage.

The row decoder 230 may select one of a plurality of memory blocks in response to a row address (X-ADDR), and may select one of the wordlines (WL) of the selected memory block. The row decoder 230 may supply voltages required for a program operation, a read operation, or an erase operation for a memory cell connected to the selected wordline (WL), and provide the voltages to the wordline (WL), the drain selection line (DSL), and the source selection line (SSL) using the reference voltages (RVs).

The source voltage generator 240 may generate a source voltage (SV) for performing a program operation, a read operation, and an erase operation on the memory cell array 100 based on a source voltage control signal (SVCS). Specifically, the source voltage generator 240 may generate a source voltage (SV) to be applied to a sourceline. The source voltage generator 240 may independently provide a source voltage (SV) to each of the plurality of memory blocks (MB1–MBm). According to an embodiment, the source voltage generator 240 may provide different source voltages (SV) to a selected memory block and an unselected memory block from among the plurality of memory blocks (MB1–MBm).

The control circuit 300 may output internal control signals for programming (writing) data (DATA) in the memory cell array 100 or reading data (DATA) from the memory cell array 100 based on a command (CMD), an address (ADDR), and a control signal (CTRL).

The control circuit 300 may generate a main voltage control signal (MVCS) to control the levels of the reference voltages (RVs) generated by the main voltage generator 220, based on the command (CMD) and control signals (CTRL). In addition, the control circuit 300 may generate a source voltage control signal (SVCS) to control the level of the source voltage (SV) generated by the source voltage generator 240.

Based on the address (ADDR), the control circuit 300 may provide a row address (X-ADDR) for selecting a wordline (WL) to the row decoder 230. The control circuit 300 may also provide a column address (Y-ADDR) for selecting a bitline (BL) to the page buffer circuit 210, based on the address (ADDR).

FIG. 3 is a diagram illustrating an example of a memory block shown in FIG. 2 according to an embodiment of the present disclosure.

Referring to FIG. 3, a memory block (MB) may correspond to any one of the plurality of memory blocks (MB1–MBm) shown in FIG. 2.

The memory block (MB) may have a three-dimensional (3D) NAND structure in which memory cells are arranged in three directions, such as for example a first direction (X), a second direction (Y), and a third direction (Z).

The memory block (MB) may include multiple pages. For convenience of description, FIG. 3 illustrates only three pages (PGn, PG(n−1), and PG(n+1)) centered on the n-th page (PGn) (where ‘n’ is an integer of 2 or greater); however, the memory block (MB) may include any number of pages in other embodiments.

Each of the pages (PGn, PG(n−1), PG(n+1)) may include M memory cells (where ‘M’ is an integer of 2 or greater) arranged in the first direction (X). Gates of the memory cells included in each of the pages (PGn, PG(n−1), PG(n+1)) may be connected to the same wordline. For example, the n-th page (PGn) may include first to m-th memory cells (MCn_1–MCn_m), and gates of the first to m-th memory cells (MCn_1–MCn_m) may be connected to the same n-th wordline (WLn).

The k-th memory cells (where ‘k’ is one of 1 to m) included in the pages (PGn, PG(n−1), PG(n+1)) may be arranged in the second direction (Y), and may be connected to each other in series. The k-th memory cells (where ‘k’ is one of 1 to m) may constitute one string, and one bitline (not illustrated) may be connected to one string. That is, the number (m) of strings included in the memory block (MB) may be equal to the number (m) of bitlines included in the memory block (MB).

In a read operation (or a verification operation) on the memory block (MB), a wordline selected from among wordlines included in the memory block (MB) will hereinafter be defined as a selected wordline (or a first wordline), and a wordline not selected from among wordlines included in the memory block (MB) will hereinafter be defined as an unselected wordline. When the n-th wordline (WLn) is the selected wordline, an (n−1)-th wordline (WL(n−1)) and an (n+1)-th wordline (WL(n+1)), which are unselected wordlines closest to the n-th wordline (WLn) in the second direction (Y), may each be defined as an adjacent unselected wordline (or a second wordline). In the present disclosure, adjacent unselected wordlines are defined as two unselected wordlines located closest to the n-th wordline (WLn) in the second direction (Y); however, according to another embodiment, adjacent unselected wordlines may be defined as three or more unselected wordlines located closest to the n-th wordline (WLn) in the second direction (Y).

A capacitance component (e.g., parasitic capacitance) may exist between adjacent wordlines. For example, a capacitance component may exist between the n-th wordline (WLn) and each of the (n−1)-th wordline (WL(n−1)) and the (n+1)-th wordline (WL(n+1)), which are the adjacent unselected wordlines located adjacent to the n-th wordline (WLn).

Due to a coupling phenomenon caused by a capacitance component between adjacent wordlines, a voltage variation of a specific wordline during a read operation (or a verification operation) on the memory block (MB) may be affected by the adjacent wordlines. In the present disclosure, a method for preventing an increase in the operating time of the memory device 10 due to this coupling phenomenon will hereinafter be described with reference to the attached drawings.

FIG. 4A is a diagram illustrating a threshold voltage distribution of memory cells included in a memory block shown in FIG. 3 according to an embodiment of the present disclosure.

Referring to FIG. 4A, a threshold voltage distribution of memory cells (e.g., MCn_1 to MCn_m) included in a memory block (MB) is illustrated. In FIG. 4A, an X-axis of the graph represents a threshold voltage (Vth), and a Y-axis of the graph represents the number of memory cells.

In the present disclosure, description will be given on the assumption that the memory cells (e.g., MCn_1 to MCn_m) are triple-level cells (TLCs) capable of storing three bits; however, the scope of the present disclosure is not limited thereto, and substantially the same technical ideas may be applied to a memory device including memory cells capable of storing a different number of bits (e.g., 2 bits, 4 bits, etc.).

A threshold voltage distribution of memory cells (e.g., MCn_1 to MCn_m) corresponding to triple-level cells (TLCs) may include eight program states. The eight program states may include an erase state (E0) and first to seventh program states (P1–P7) in which threshold voltages sequentially increase. The erase state (E0) may refer to a state in which data stored in a memory cell is erased and the memory cell is not yet programmed. The first to seventh program states (P1–P7) may indicate states programmed using program voltages, which sequentially increase from the first program state (P1) to the seventh program state (P7). That is, a memory cell corresponding to the erase state (E0) may have the lowest threshold voltage, the threshold voltage may sequentially increase from the first program state (P1) to the seventh program state (P7), and a memory cell corresponding to the seventh program state (P7) may have the highest threshold voltage.

The erase state (E0) and the first to seventh program states (P1–P7) may be identified using first to seventh read voltages (R1–R7) that sequentially increase. Each of the first to seventh read voltages (R1–R7) may correspond to a voltage between adjacent states. For example, the first read voltage (R1) may be a voltage between the erase state (E0) and the first program state (P1), the fourth read voltage (R4) may be a voltage between the third program state (P3) and the fourth program state (P4), and the seventh read voltage (R7) may be a voltage between the sixth program state (P6) and the seventh program state (P7).

In a read operation (or a verification operation) on the memory block (MB), one of the first to seventh read voltages (R1–R7) may be applied to a selected wordline, and a pass voltage (Vpass) may be applied to an unselected wordline.

Each of the erase state (E0) and the first to seventh program states (P1–P7) may represent data including three bits (i.e., a least significant bit (LSB), a central significant bit (CSB), and a most significant bit (MSB)).

The most significant bit (MSB), the central significant bit (CSB), and the least significant bit (LSB) represented by the erase state (E0) may be set to 1, 1, and 1, respectively. The MSB, CSB, and LSB represented by the first program state (P1) may be set to 1, 1, and 0, respectively. The MSB, CSB, and LSB represented by the second program state (P2) may be 1, 0, and 1, respectively. The MSB, CSB, and LSB represented by the third program state (P3) may be set to 1, 0, and 0, respectively. The MSB, CSB, and LSB represented by the fourth program state (P4) may be set to 0, 1, and 1, respectively. The MSB, CSB, and LSB represented by the fifth program state (P5) may be set to 0, 1, and 0, respectively. The MSB, CSB, and LSB represented by the sixth program state (P6) may be set to 0, 0, and 1, respectively. The MSB, CSB, and LSB represented by the seventh program state (P7) may be set to 0, 0, and 0, respectively.

FIG. 4B is a table illustrating an order of using read voltages in a read operation with respect to a threshold voltage distribution of memory cells shown in FIG. 4A according to an embodiment of the present disclosure.

Referring to FIG. 4B, an order (sequence) of read voltages to be applied to a selected wordline for reading the most significant bit (MSB), the central significant bit (CSB), and the least significant bit (LSB) represented, for each of the erase state (E0) and the first to seventh program states (P1–P7), is illustrated. According to another embodiment, the order (sequence) of read voltages applied to the selected word lines to read the most significant bit (MSB), the central significant bit (CSB), and the least significant bit (LSB) may be varied.

In order to read the most significant bit (MSB), a fifth read voltage (R5) may be applied to the selected wordline during a first read action (denoted by ‘First Read’). Thereafter, in order to read the most significant bit (MSB), a first read voltage (R1) may be applied to the selected wordline during a subsequent read action (denoted by ‘Second Read’).

In addition, in order to read the central significant bit (CSB), a sixth read voltage (R6) may be applied to the selected wordline during the first read action (First Read). Thereafter, in order to read the central significant bit (CSB), a fourth read voltage (R4) and a second read voltage (R2) may be sequentially applied to the selected wordline during a subsequent read action (Second Read).

In order to read the least significant bit (LSB), a seventh read voltage (R7) may be applied to the selected wordline during a first read action (First Read). Thereafter, in order to read the least significant bit (LSB), a third read voltage (R3) may be applied to the selected wordline during a second read action (Second Read).

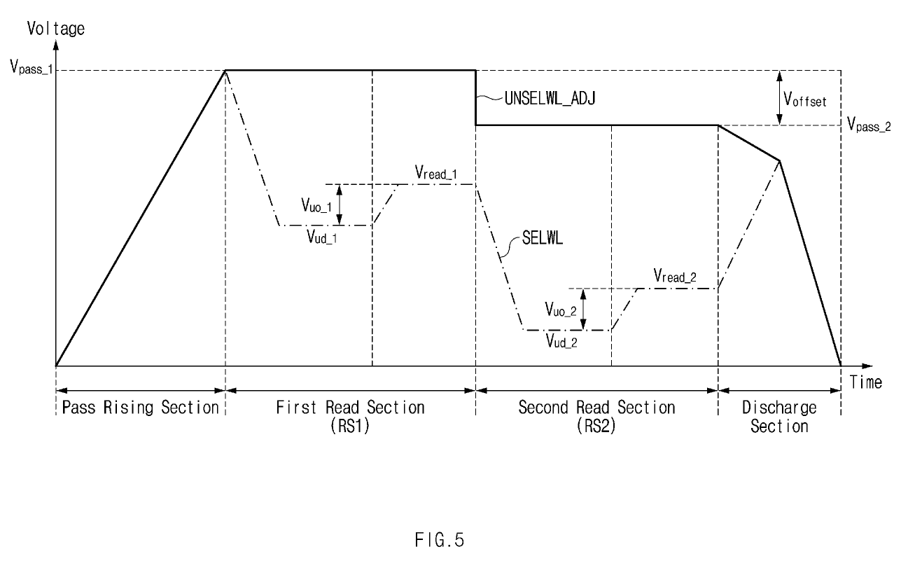

FIG. 5 is a graph illustrating an example of voltages applied to a selected wordline and an unselected wordline during a read operation according to an embodiment of the present disclosure.

Referring to FIG. 5, a selected wordline voltage (SELWL), which is a voltage applied to a selected wordline during a read operation, and an adjacent unselected wordline voltage (UNSELWL_ADJ), which is a voltage applied to an adjacent unselected wordline, are illustrated. In the graph of FIG. 5, an X-axis represents time, and a Y-axis represents voltage.

A read operation may include a pass rising section, a first read section (RS1), a second read section (RS2), and a discharge section.

The pass rising section may be a time section in which each of a selected wordline voltage (SELWL), which is a voltage applied to a selected wordline, and an adjacent unselected wordline voltage (UNSELWL_ADJ), which is a voltage applied to an adjacent unselected wordline, rises from a ground voltage (e.g., 0 V) to a first pass voltage (V_{pass_1}). In addition, during the pass rising section, voltages applied to unselected wordlines other than the adjacent unselected wordlines, from among the wordlines of the memory block (MB), may also rise from the ground voltage (e.g., 0 V) to the first pass voltage (V_{pass_1}), similar to the adjacent unselected wordline voltage (UNSELWL_ADJ). The first pass voltage (V_{pass_1}) may refer to a pass voltage that turns on a memory cell regardless of a state (e.g., any one of the erase state (E0) and the first to seventh program states P1–P7) of the memory cell.

The first read section (RS1) may be a time period during which a voltage of the selected wordline is set to a first target read voltage (V_{read_1}). After the voltage of the selected wordline becomes equal to the first target read voltage (V_{read_1}), data stored in a selected memory cell connected to the selected wordline is read.

Referring to FIG. 4B, when the first read section (RS1) corresponds to a first read (First Read) for reading the most significant bit (MSB), the first target read voltage (V_{read_1}) may be the fifth read voltage (R5). When the first read section (RS1) corresponds to a first read for reading the central significant bit (CSB), the first target read voltage (V_{read_1}) may be the sixth read voltage (R6). When the first read section (RS1) corresponds to a first read (First Read) for reading the least significant bit (LSB), the first target read voltage (V_{read_1}) may be the seventh read voltage (R7).

In order to set the voltage of the selected wordline to the first target read voltage (V_{read_1}), the selected wordline voltage (SELWL) may be maintained for a predetermined time at a first underdrive voltage (V_{ud_1}) that is lower than the first target read voltage (V_{read_1}) by a first underdrive offset voltage (V_{uo_1}), and then transition to the first target read voltage (V_{read_1}). Here, the reason why the selected wordline voltage (SELWL) does not transition directly to the first target read voltage (V_{read_1}), but instead transitions to the first target read voltage (V_{read_1}) via the first underdrive voltage (V_{ud_1}), is to reduce a first selection settling time. The first selection settling time may refer to the time required for the voltage of the selected wordline to become equal to the first target read voltage (V_{read_1}) after the start of the first read section (RS1). If the selected wordline voltage (SELWL) transitions directly to the first target read voltage (V_{read_1}), then the first selection settling time may be relatively increased due to a coupling phenomenon caused by a capacitance component between the selected wordline and the adjacent unselected wordlines. As illustrated in FIG. 5, when the selected wordline voltage (SELWL) transitions to the first target read voltage (V_{read_1}) via the first underdrive voltage (V_{ud_1}), which is lower than the first target read voltage (V_{read_1}), the influence of the coupling phenomenon may be reduced, thereby relatively decreasing the first selection settling time.

The first underdrive voltage (V_{ud_1}) and the first underdrive offset voltage (V_{uo_1}) may be values experimentally determined such that the first selection settling time satisfies conditions required by a system (e.g., a host or the memory controller 20).

Meanwhile, the adjacent unselected wordline voltage (UNSELWL_ADJ) may maintain the first pass voltage (V_{pass_1}) during the first read section (RS1). Due to a coupling phenomenon caused by a capacitance component between the selected wordline and the adjacent unselected wordlines, as the voltage of the selected wordline decreases after the start of the first read section (RS1), the voltage of the adjacent unselected wordline may also decrease. The time required for the voltage of an adjacent unselected wordline to become equal to the first pass voltage (V_{pass_1}) after the start of the first read section (RS1) may be defined as a first unselected settling time.

An operation of reading data stored in a selected memory cell connected to the selected wordline may be performed after the first selection settling time or the first unselected settling time, whichever is longer, has elapsed from the start of the first read section (RS1).

The second read section (RS2) may be a time period in which the voltage of the selected wordline is set to a second target read voltage (V_{read_2}), and after the voltage of the selected wordline becomes equal to the second target read voltage (V_{read_2}), data stored in a selected memory cell connected to the selected wordline is read.

When the second read section (RS2) corresponds to a subsequent read action for reading the most significant bit (MSB), the second target read voltage (V_{read_2}) may be the first read voltage (R1). When the second read section (RS2) corresponds to a subsequent read action for reading the central significant bit (CSB), the second target read voltage (V_{read_2}) may be the fourth read voltage (R4) or the second read voltage (R2). When the second read section (RS2) corresponds to a subsequent read action for reading the least significant bit (LSB), the second target read voltage (V_{read_2}) may be the third read voltage (R3).

In order to set the voltage of the selected wordline to the second target read voltage (V_{read_2}), the selected wordline voltage (SELWL) may be maintained for a predetermined time at a second underdrive voltage (V_{ud_2}) that is lower than the second target read voltage (V_{read_2}) by a second underdrive offset voltage (V_{uo_2}), and then transition to the second target read voltage (V_{read_2}). Here, the reason why the selected wordline voltage (SELWL) does not transition directly to the second target read voltage (V_{read_2}), but instead transitions to the second target read voltage (V_{read_2}) via the second underdrive voltage (V_{ud_2}), is to reduce a second selection settling time. The second selection settling time may refer to a time required for the voltage of the selected wordline to become equal to the second target read voltage (V_{read_2}) after the start of the second read section (RS2). If the selected wordline voltage (SELWL) transitions directly to the second target read voltage (V_{read_2}), the second selection settling time may be relatively increased due to a coupling phenomenon caused by a capacitance component between the selected wordline and the adjacent unselected wordlines. As illustrated in FIG. 5, when the selected wordline voltage (SELWL) transitions to the second target read voltage (V_{read_2}) via the second underdrive voltage (V_{ud_2}), which is lower than the second target read voltage (V_{read_2}), the influence of the coupling phenomenon may be reduced, thereby relatively decreasing the second selection settling time.

The second underdrive voltage (V_{ud_2}) and the second underdrive offset voltage (V_{uo_2}) may be values experimentally determined such that the second selection settling time satisfies conditions required by a system (e.g., a host or the memory controller 20).

Meanwhile, during the second read section (RS2), the adjacent unselected wordline voltage (UNSELWL_ADJ) may maintain a second pass voltage (V_{pass_2}) that is lower than the first pass voltage (V_{pass_1}) by an offset voltage (V_{offset}). That is, the adjacent unselected wordline voltage (UNSELWL_ADJ) may maintain the first pass voltage (V_{pass_1}) during the first read section (RS1) and then transition to the second pass voltage (V_{pass_2}) during the second read section (RS2). The second pass voltage (V_{pass_2}) may be lower than the first pass voltage (V_{pass_1}) and, like the first pass voltage (V_{pass_1}), may refer to a pass voltage that turns on a memory cell regardless of a state (e.g., one of the erase state (E0) and the first to seventh program states (P1–P7)) of the memory cell.

Due to a coupling phenomenon caused by a capacitance component between the selected wordline and the adjacent unselected wordlines, as the voltage of the selected wordline decreases after the start of the second read section (RS2), the voltage of the adjacent unselected wordline may also decrease. A time required for the voltage of the adjacent unselected wordline to become equal to the second pass voltage (V_{pass_2}) after the start of the second read section (RS2) may be defined as a second unselected settling time.

If the adjacent unselected wordline voltage (UNSELWL_ADJ) maintains the first pass voltage (V_{pass_1}) in the second read section (RS2), as in the first read section (RS1), instead of the second pass voltage (V_{pass_2}), then due to the coupling phenomenon caused by a capacitance component between the selected wordline and the adjacent unselected wordline, the voltage of the adjacent unselected wordline may also decrease as the voltage of the selected wordline decreases after the start of the second read section (RS2). In this case, because the second underdrive voltage (V_{ud_2}) applied to the selected wordline after the start of the second read section (RS2) is lower than the first underdrive voltage (V_{ud_1}) applied to the selected wordline after the start of the first read section (RS1), the coupling strength between the selected wordline and the adjacent unselected wordline may become stronger than that in the first read section (RS1). Accordingly, the time required for the voltage of the adjacent unselected wordline to become equal to the first pass voltage (V_{pass_1}) after the start of the second read section (RS2) may be longer than the first unselected settling time.

However, as illustrated in FIG. 5, when the adjacent unselected wordline voltage (UNSELWL_ADJ) maintains the second pass voltage (V_{pass_2}) in the second read section (RS2), even if the second underdrive voltage (V_{ud_2}), which is applied to the selected wordline after the start of the second read section (RS2), becomes lower than the first underdrive voltage (V_{ud_1}), the coupling strength between the selected wordline and the adjacent unselected wordlines may become similar to that in the first read section (RS1). Accordingly, the time required for the voltage of an adjacent unselected wordline to become equal to the second pass voltage (V_{pass_2}) after the start of the second read section (RS2) may become similar to the first unselected settling time.

An offset voltage (V_{offset}), which is a difference between the first pass voltage (V_{pass_1}) and the second pass voltage (V_{pass_2}), may be determined based on at least one of a wordline characteristic index and a read characteristic index.

The wordline characteristic index may be determined based on at least one of a resistance of a selected wordline, a magnitude of a capacitance component with an adjacent unselected wordline, a magnitude of a capacitance component between the selected wordline and a channel of a memory cell connected to the selected wordline, or magnitudes of parasitic capacitance components related to the other wordlines. The wordline characteristic index may increase as the resistance of the wordline increases, as the magnitude of the capacitance component with the adjacent wordline increases, as the magnitude of the capacitance component between the wordline and the channel of the memory cell connected to the wordline increases, and as the magnitudes of parasitic capacitance components related to the other wordlines increase. Conversely, the wordline characteristic index may decrease as the resistance of the wordline decreases, as the magnitude of the capacitance component with the adjacent wordline decreases, as the magnitude of the capacitance component between the wordline and the channel of the memory cell connected to the wordline decreases, and as the magnitudes of parasitic capacitance components related to the other wordlines decrease. The wordline characteristic index may vary for each wordline, and the offset voltage (V_{offset}) may be proportional to the wordline characteristic index.

The read characteristic index may be determined based on at least one of a level of the second target read voltage (V_{read_2}), the second underdrive offset voltage (V_{uo_2}), or the amount of time (hereinafter referred to as an “underdrive duration”) during which the second underdrive voltage (V_{ud_2}) is maintained. The read characteristic index may increase as the level of the second target read voltage (V_{read_2}) increases, as the second underdrive offset voltage (V_{uo_2}) increases, and as the underdrive duration becomes longer. The read characteristic index may decrease as the level of the second target read voltage (V_{read_2}) decreases, as the second underdrive offset voltage (V_{uo_2}) decreases, and as the underdrive duration becomes shorter. The read characteristic index may vary depending on a read target (e.g., MSB, CSB, or LSB) to be read and the underdrive settings, and the offset voltage (V_{offset}) may be proportional to the read characteristic index.

The discharge section may be a time period in which the selected wordline voltage (SELWL) and the adjacent unselected wordline voltage (UNSELWL_ADJ) are discharged to a ground voltage (e.g., 0 V). In some embodiments, when a line to which the selected wordline voltage (SELWL) is applied and a line to which the adjacent unselected wordline voltage (UNSELWL_ADJ) is applied are connected to each other, the selected wordline voltage (SELWL) and the adjacent unselected wordline voltage (UNSELWL_ADJ) may converge to the same voltage, after which the selected wordline voltage (SELWL) and the adjacent unselected wordline voltage (UNSELWL_ADJ) may transition to the ground voltage (e.g., 0 V).

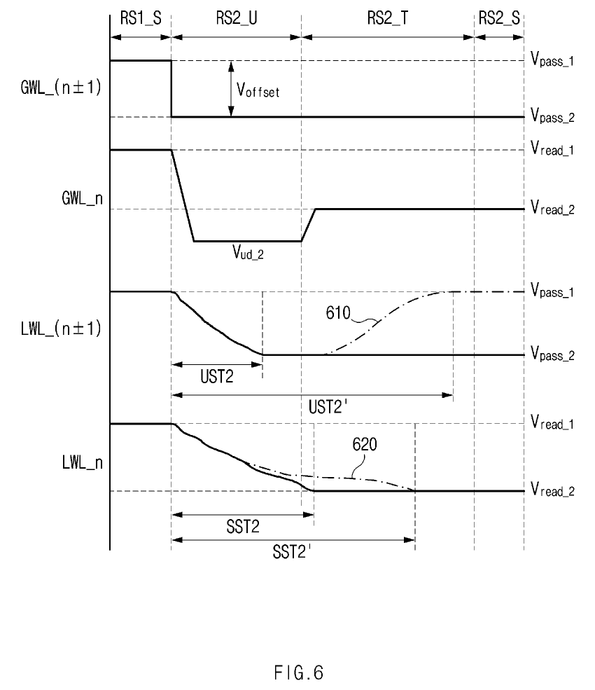

FIG. 6 is a graph illustrating example actions (or behaviors) of wordlines in response to voltages changing as shown in FIG. 5 according to an embodiment of the present disclosure.

Referring to FIG. 6, a wordline connected between a row decoder 230 and memory cells of a memory cell array 100 in FIG. 2 may include a global wordline GWL and a local wordline LWL. The global wordline may be connected to the row decoder 230, and may receive a voltage (e.g., a pass voltage or a read voltage) output from the row decoder 230. The local wordline may be connected to memory cells of the memory cell array 100, and may supply the voltage received from the global wordline to the memory cells. In some embodiments, a switching element (e.g., a pass transistor) may be connected between the global wordline and the local wordline.

In FIG. 6, it is assumed that the n-th wordline is a selected wordline, and the (n+1)-th wordline and the (n−1)-th wordline are adjacent unselected wordlines.

The n-th global wordline (GWL_n), which is a global wordline of the n-th wordline, may directly receive the selected wordline voltage (SELWL) from the row decoder 230 and thus may have the same waveform as the selected wordline voltage (SELWL) described with reference to FIG. 5.

The (n+1)-th global wordline (GWL_(n+1)), which is a global wordline of the (n+1)-th wordline, may directly receive the adjacent unselected wordline voltage (UNSELWL_ADJ) from the row decoder 230, and thus may have the same waveform as the adjacent unselected wordline voltage (UNSELWL_ADJ) described with reference to FIG. 5. Similarly, the (n−1)-th global wordline (GWL_(n−1)), which is a global wordline of the (n−1)-th wordline, may directly receive the adjacent unselected wordline voltage (UNSELWL_ADJ) from the row decoder 230, and thus may have the same waveform as the adjacent unselected wordline voltage (UNSELWL_ADJ) described with reference to FIG. 5.

FIG. 6 illustrates waveforms of the n-th global wordline (GWL_n) and the (n±1)-th global wordlines (GWL_(n±1)), waveforms of the n-th local wordline (LWL_n), which is a local wordline of the n-th wordline, waveforms of the (n+1)-th local wordline (LWL_(n+1)), which is a local wordline of the (n+1)-th wordline, and waveforms of the (n−1)-th local wordline (LWL_(n−1)) (i.e., the (n±1)-th local wordline (LWL_(n±1))).

In addition, each of the read sections (RS1, RS2) described with reference to FIG. 5 may include an underdrive section in which an underdrive voltage (Vud_1 or Vud_2) is applied to the selected wordline, a setting section in which the selected wordline and the unselected wordline are respectively set to a read voltage and a pass voltage, and a sensing section in which data stored in a selected memory cell connected to the selected wordline is read. Here, the setting section may be a time section in which a voltage of a global wordline corresponding to the selected wordline becomes equal to a voltage of a local wordline corresponding to the selected wordline, and a voltage of a global wordline corresponding to the unselected wordline becomes equal to a voltage of a local wordline corresponding to the unselected wordline.

FIG. 6 illustrates a first sensing section (RS1_S) of the first read section (RS1), a second underdrive section (RS2_U) of the second read section (RS2), a second setting section (RS2_T) of the second read section (RS2), and a second sensing section (RS2_S) of the second read section (RS2).

In the first sensing section (RS1_S), the n-th global wordline (GWL_n) and the n-th local wordline (LWL_n) may have the first target read voltage (Vread_1), and the (n±1)-th global wordlines (GWL_(n±1)) and the (n±1)-th local wordlines (LWL_(n±1)) may have the first pass voltage (Vpass_1). A page buffer circuit 210 of FIG. 2 may read data stored in a selected memory cell connected to the n-th local wordline (LWL_n), which is the selected wordline.

In the second underdrive section (RS2_U), a voltage of the n-th global wordline (GWL_n) may transition to a second underdrive voltage (Vud_2), which is lower than the second target read voltage (Vread_2). Accordingly, a voltage of the n-th local wordline (LWL_n) connected to the n-th global wordline (GWL_n) may decrease from the first target read voltage (Vread_1) toward the second target read voltage (Vread_2). At this time, due to a capacitance component present in the n-th local wordline (LWL_n), the voltage drop may proceed with a gentler slope than that of the n-th global wordline (GWL_n), but other embodiments are not limited thereto. Since the voltage of the n-th global wordline (GWL_n) is set to the second underdrive voltage (V_{ud_2}), which is lower than the second target read voltage (V_{read_2}), the slope of such voltage drop may become steeper.

In addition, a voltage of the (n±1)-th global wordlines (GWL_(n±1)) may transition to a second pass voltage (V_{pass_2}) that is lower than the first pass voltage (Vpass_1) by an offset voltage (Voffset). Accordingly, a voltage of the (n±1)-th local wordlines (LWL_(n±1)) connected to the (n±1)-th global wordlines (GWL_(n±1)) may decrease from the first pass voltage (V_{pass_1}) toward the second pass voltage (V_{pass_2}). At this time, due to a coupling phenomenon between the n-th local wordline (LWL_n) and the (n±1)-th local wordlines (LWL_(n±1)), a voltage drop of the (n±1)-th local wordlines (LWL_(n±1)) may be accelerated. The voltage of the (n±1)-th local wordlines (LWL_(n±1)) may decrease until reaching the second pass voltage (V_{pass_2}). A time from a start point of the second underdrive section (RS2_U) to a time point at which the voltage of the (n±1)-th local wordlines (LWL_(n±1)) becomes equal to the second pass voltage (V_{pass_2}) may be defined as a second unselected settling time (UST2).

In the second setting section (RS2_T), a voltage of the n-th global wordline (GWL_n) may transition to the second target read voltage (V_{read_2}), which is higher than the second underdrive voltage (V_{ud_2}). Accordingly, a voltage of the n-th local wordline (LWL_n) connected to the n-th global wordline (GWL_n) may decrease until reaching the second target read voltage (V_{read_2}) without decreasing to a voltage lower than the second target read voltage (V_{read_2}). A time period from a start point of the second underdrive section (RS2_U) to a time point at which the voltage of the n-th local wordline (LWL_n) becomes equal to the second target read voltage (V_{read_2}) may be defined as a second selection settling time (SST2).

If the voltage of the (n±1)-th global wordlines (GWL_(n±1)) is maintained at the first pass voltage (V_{pass_1}) during the second underdrive section (RS2_U) and the second setting section (RS2_T), then the voltage of the (n±1)-th local wordlines (LWL_(n±1)), which has been lowered due to a coupling phenomenon between the n-th local wordline (LWL_n) and the (n±1)-th local wordlines (LWL_(n±1)), may have a waveform 610 that gradually rises again to the first pass voltage (V_{pass_1}). Accordingly, in this case, a second unselected settling time (UST2’), which is a time from a start point of the second underdrive section (RS2_U) to a time point at which the voltage of the (n±1)-th local wordlines (LWL_(n±1)) becomes equal to the first pass voltage (V_{pass_1}), may be relatively longer than the second unselected settling time (UST2) described above.

That is, when the voltage of the (n±1)-th global wordlines (GWL_(n±1)) transitions to the second pass voltage (V_{pass_2}), which is lower than the first pass voltage (V_{pass_1}) by the offset voltage (V_{offset}), during the second underdrive section (RS2_U) and the second setting section (RS2_T), a time required for the (n±1)-th local wordlines (LWL_(n±1)) to be set to the pass voltage may be shortened.

If the voltage of the (n±1)-th global wordlines (GWL_(n±1)) is maintained at the first pass voltage (V_{pass_1}) during the second underdrive section (RS2_U) and the second setting section (RS2_T), and the voltage of the (n±1)-th local wordlines (LWL_(n±1)) has a waveform 610 that gradually rises again to the first pass voltage (V_{pass_1}), a voltage drop rate of the n-th local wordline (LWL_n) may be reduced due to a coupling phenomenon between the n-th local wordline (LWL_n) and the (n±1)-th local wordlines (LWL_(n±1)). In this case, the voltage of the n-th local wordline (LWL_n) may have a waveform 620 that reaches the second target read voltage (V_{read_2}) relatively slowly. Accordingly, in this case, a second selection settling time (SST2’), which is a time from a start point of the second underdrive section (RS2_U) to a time point at which the voltage of the n-th local wordline (LWL_n) becomes equal to the second target read voltage (V_{read_2}), may be relatively longer than the second selection settling time (SST2) described above.

That is, when the voltage of the (n±1)-th global wordlines (GWL_(n±1)) transitions to the second pass voltage (V_{pass_2}), which is lower than the first pass voltage (V_{pass_1}) by the offset voltage (V_{offset}), during the second underdrive section (RS2_U) and the second setting section (RS2_T), the time required for the n-th local wordline (LWL_n) to be set to the second target read voltage (V_{read_2}) may be shortened.

In the second sensing section (RS2_S), the n-th global wordline (GWL_n) and the n-th local wordline (LWL_n) may have reached the second target read voltage (V_{read_2}), and the (n±1)-th global wordlines (GWL_(n±1)) and the (n±1)-th local wordlines (LWL_(n±1)) may have reached the second pass voltage (V_{pass_2}). The page buffer circuit 210 may read data stored in a selected memory cell connected to the n-th local wordline (LWL_n), which is the selected wordline.

As is apparent from the above description, the semiconductor memory device according to the embodiments of the present disclosure may reduce the amount of time needed for setting voltages for a selected wordline and an unselected wordline, thereby improving the speed of a read operation.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. A semiconductor memory device comprising:
a memory block including a plurality of memory cells;
a first wordline connected to a selected memory cell from among the plurality of memory cells;
a second wordline disposed adjacent to the first wordline; and
a row decoder configured to transmit a first pass voltage to the second wordline in a first read time period and to transmit a second pass voltage lower than the first pass voltage to the second wordline in a second read time period.

2. The semiconductor memory device according to claim 1, wherein the row decoder is configured to:
during the first read time period, sequentially transmit, to the first wordline, a first underdrive voltage, which is lower than a first target read voltage, and then the first target read voltage.

3. The semiconductor memory device according to claim 2, wherein the row decoder is configured to:
during the second read time period, sequentially transmit, to the first wordline, a second underdrive voltage, which is lower than a second target read voltage, and then the second target read voltage.

4. The semiconductor memory device according to claim 3, wherein:
the first target read voltage is higher than the second target read voltage; and
the first underdrive voltage is higher than the second underdrive voltage.

5. The semiconductor memory device according to claim 3, wherein:
the selected memory cell is a triple-level cell storing a most significant bit (MSB), a central significant bit (CSB), and a least significant bit (LSB);
the selected memory cell corresponds to one of an erase state and first to seventh program states in which threshold voltages sequentially increase; and
the erase state and the first to seventh program states are identified by first to seventh read voltages that sequentially increase.

6. The semiconductor memory device according to claim 5, wherein:
the first read time period and the second read time period are time periods for reading the most significant bit (MSB);
the first target read voltage is the fifth read voltage; and
the second target read voltage is the first read voltage.

7. The semiconductor memory device according to claim 5, wherein:
the first read time period and the second read time period are time periods for reading the central significant bit (CSB);
the first target read voltage is the sixth read voltage; and
the second target read voltage is the second read voltage or the fourth read voltage.

8. The semiconductor memory device according to claim 5, wherein:
the first read time period and the second read time period are time periods for reading the least significant bit (LSB);
the first target read voltage is the seventh read voltage; and
the second target read voltage is the third read voltage.

9. The semiconductor memory device according to claim 1, wherein:
the second pass voltage is lower than the first pass voltage by an offset voltage,
wherein
the offset voltage is determined based on at least one of a wordline characteristic index and a read characteristic index.

10. The semiconductor memory device according to claim 9, wherein:
the wordline characteristic index is determined based on at least one of a resistance of the first wordline, a magnitude of a capacitance component between the first wordline and the second wordline, or a magnitude of a capacitance component between the first wordline and a channel of the selected memory cell.

11. The semiconductor memory device according to claim 10, wherein:
the wordline characteristic index increases as the resistance of the first wordline increases, as the magnitude of the capacitance component between the first wordline and the second wordline increases, or as the magnitude of the capacitance component between the first wordline and the channel of the selected memory cell increases.

12. The semiconductor memory device according to claim 9, wherein:
the offset voltage is proportional to the wordline characteristic index.

13. The semiconductor memory device according to claim 9, wherein:
the row decoder sequentially transmits, to the first wordline in the second read time period, a second underdrive voltage, which is lower than a second target read voltage, and then the second target read voltage; and
the read characteristic index is determined based on at least one of a level of the second target read voltage, a difference between the second underdrive voltage and the second target read voltage, or a time during which the second underdrive voltage is maintained.

14. The semiconductor memory device according to claim 13, wherein:
the read characteristic index increases as the level of the second target read voltage increases, as the difference between the second underdrive voltage and the second target read voltage increases, or as the time during which the second underdrive voltage is maintained becomes longer.

15. The semiconductor memory device according to claim 9, wherein:
the offset voltage is proportional to the read characteristic index.

16. A method for operating a semiconductor memory device comprising:
increasing voltages of a first wordline, connected to a selected memory cell from among multiple memory cells, and a second wordline disposed adjacent to the first wordline to a first pass voltage;
transmitting the first pass voltage to the second wordline in a first read section; and
transmitting a second pass voltage lower than the first pass voltage to the second wordline in a second read section.

17. The method according to claim 16, further comprising:
sequentially transmitting, to the first wordline in the first read section, a first underdrive voltage, which is lower than a first target read voltage, and the first target read voltage.

18. The method according to claim 17, further comprising:
sequentially transmitting, to the first wordline in the second read section, a second underdrive voltage, which is lower than a second target read voltage, and the second target read voltage.

19. The method according to claim 18, wherein:
the first target read voltage is higher than the second target read voltage; and
the first underdrive voltage is higher than the second underdrive voltage.

20. A semiconductor memory device comprising:
a memory block including a plurality of memory cells;
a selected wordline connected to a selected memory cell from among the plurality of memory cells; and
an unselected wordline disposed adjacent to the selected wordline and configured to sequentially receive a first pass voltage and a second pass voltage lower than the first pass voltage in an operation for reading one or more bits stored in the selected memory cell.
